(19) United States
(12) Patent Application Publication
(10) Pub. No.: US 2019/0302176 A1
(43) Pub. Date: Oct. 3, 2019

(54) COMPENSATION FOR GROUND RETURN DIFFERENCES

(71) Applicant: ABB Schweiz AB, Baden (CH)

(72) Inventors: David J. Mielnik, Painesville, OH (US); Thomas Heilman, Wickliffe, OH (US)

(21) Appl. No.: 16/443,094

(22) Filed: Jun. 17, 2019

Related U.S. Application Data
(63) Continuation of application No. PCT/US17/66951, filed on Dec. 18, 2017.
(60) Provisional application No. 62/435,468, filed on Dec. 16, 2016.

(51) Int. Cl. G01R 31/28; G01D 5/14

(52) U.S. Cl. CPC G01R 31/2829; G01D 5/14

(57) ABSTRACT

An approach is disclosed capable of correcting for errors introduced into a printed circuit board, but other applications are also contemplated. The approach includes assessing resistance differences in various ground return portions of circuit pathways and calculating an offset for each of those pathways.

### TECHNICAL FIELD

The present invention generally relates to compensation in electrical signals that share a ground return, and more particularly, but not exclusively, to error compensation in printed circuit boards.

### BACKGROUND

Providing correction for known circuit resistances remains an area of interest. Some existing systems have various shortcomings relative to certain applications. Accordingly, there remains a need for further contributions in this area of technology.

### SUMMARY

One embodiment of the present invention is a unique circuit for compensating for known error resistances. Other embodiments include apparatuses, systems, devices, hardware, methods, and combinations for compensating for different resistances over different segments of a common or shared ground return line. Further embodiments, forms, features, aspects, benefits, and advantages of the present application shall become apparent from the description and figures provided herewith.

### BRIEF DESCRIPTION OF THE FIGURES

FIG. 1 depicts an embodiment of a printed circuit board having error resistances.

FIG. 2 depicts an embodiment of a printed circuit board having error resistances and a formula to adjust for those resistances.

FIG. 3 depicts a first part of C program implementation of the formula depicted in FIG. 2.

FIG. 4 depicts a continuation of code from FIG. 3 which constitutes a second part of C program implementation of the formula depicted in FIG. 2.

FIG. 5 depicts a continuation of code from FIG. 4 which constitutes a final part of C program implementation of the formula depicted in FIG. 2.

### DETAILED DESCRIPTION OF THE ILLUSTRATIVE EMBODIMENTS

For the purposes of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates.

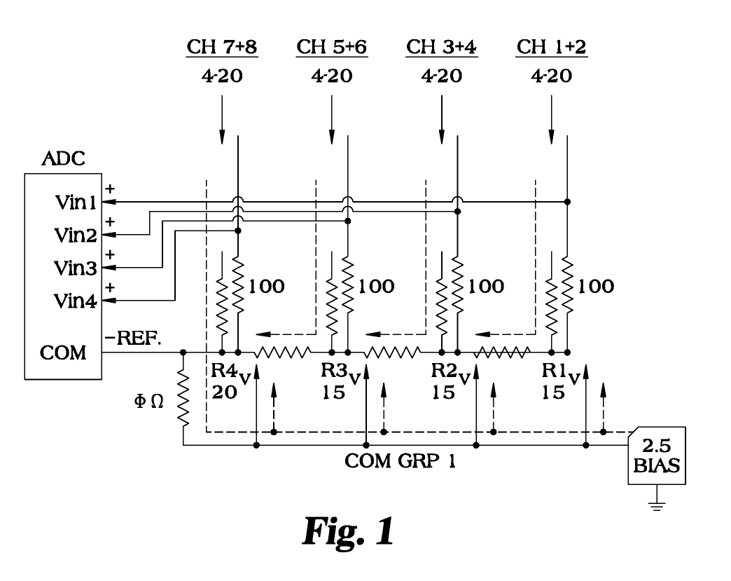

With reference to FIG. 1, a diagram is illustrated which depicts a technique to apply correction offsets to electrical values communicated over various channels. In one embodiment the techniques used herein can be used to correct errors in a printed circuit board, an example embodiment of which is described further below where an error associated with a single channel or lane can electrically couple itself into the remaining channels that are otherwise defect free.

The channels in FIG. 1 can represent measurement channels such as would be used to provide measurement information from a sensor or other like device, to set forth just one nonlimiting example. As seen in the figure, eight separate channels are arranged in four sets of pairs (or “lanes”). Each pair, or lane, is coupled with a ground return at different locations, or if not coupled in a sense of being connected each pair or lane includes a portion of the circuit pathway that is considered the ground return for purposes of the analysis and correction herein. The ground return can take various forms including a ground return line, a ground return trace, etc. The different locations result in different resistances in the ground return (i.e. R1, R2, R3, and R4).

Although the channels are shown in pairings, not all embodiments need to include pairs. Additionally and/or alternatively, although four separate locations are shown that the channels return to ground, any number of separate locations greater than or equal to two are contemplated. Thus, at a minimum two separate channels configured to return at two separate locations are contemplated, with greater numbers of channels, either paired or not, and at possibly other locations than those depicted.

FIG. 1 depicts differences in the error resistances where lanes 1-3 have similar resistance values of 15 milli-ohms in distinct portions of the ground return (e.g. separate copper trace segments), while lane 4 has a resistance value of 20 milli-ohms in its distinct portion of ground return. Other embodiments can include larger numbers of variations between the lanes and the values of the error resistances, no limitation is hereby intended by the depiction shown. Voltage measurements can be taken across each of the separate reference resistors which can be used to determine current in each of the channels.

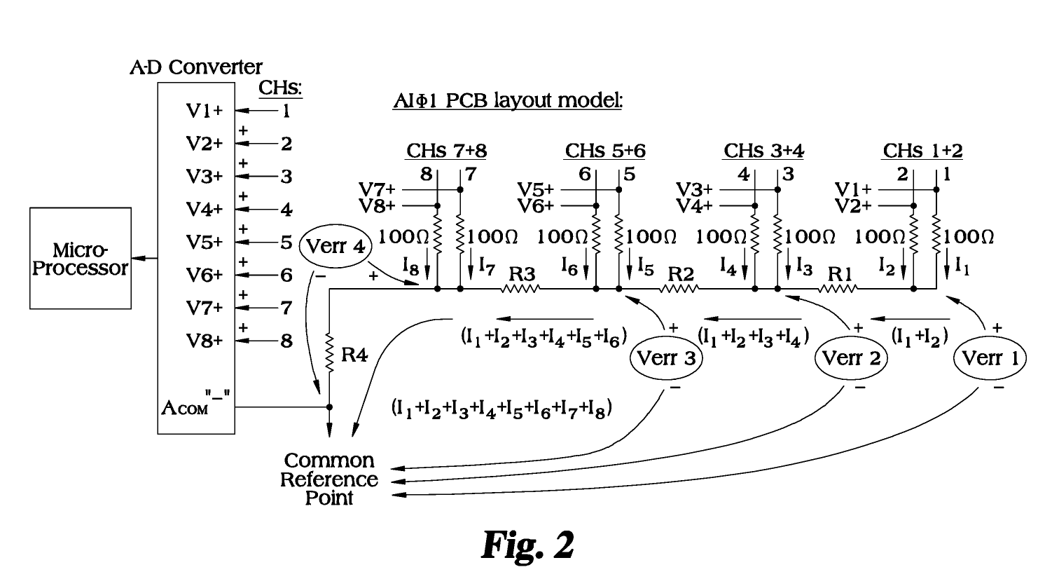

FIG. 2 illustrates another depiction of the setup from FIG. 1, along with a compensation approach to account for the different resistances in the distinct portions of the associated ground return. In an embodiment where the channels represent electrical information generated from sensors, it will be appreciated that the channels can vary independent of one another to the extent that the sensors are independent of one another.

In the illustrated embodiment, it is contemplated that the various resistances of the return to ground (as seen from the various relevant locations at which the channels turn to ground return) are assessed in some manner and known in advance. Such assessment can include direct measurements or estimations. During operation of the system when electrical information is available on two or more of the channels, assessment can also be taken of current flow in each of the separate channels. Such assessment can be via calculation where a voltage across a reference resistor (i.e. the 100 Ohm resistor depicted in each channel) is measured and an electrical current subsequently determined through Ohms law. Current flow information can be coupled with the assessed resistance in each of the ground returns and an error offset can be calculated as a result. The compensation approach is shown at the bottom of FIG. 2 and can be used continuously (or near continuous) in real-time depending on the implementation of the offset correction set forth herein.

Compensation formulas can thus take the following form:

Vₑᵣᵣ₁=R₄(I₁+I₂+I₃+I₄+I₅+I₆+I₇+I₈)+R₃(I₁+I₂+I₃+I₄+I₅+I₆)+R₂(I₁+I₂+I₃+I₄)+R₁(I₁+I₂) Eq. 1:

Vₑᵣᵣ₂=R₄(I₁+I₂+I₃+I₄+I₅+I₆+I₇+I₈)+R₃(I₁+I₂+I₃+I₄+I₅+I₆)+R₂(I₁+I₂+I₃+I₄) Eq. 2:

Vₑᵣᵣ₃=R₄(I₁+I₂+I₃+I₄+I₅+I₆+I₇+I₈)+R₃(I₁+I₂+I₃+I₄+I₅+I₆) Eq. 3:

Vₑᵣᵣ₄=R₄(I₁+I₂+I₃+I₄+I₅+I₆+I₇+I₈) Eq. 4:

The final “compensated” values for the eight channels are thus:

V_{1comp}=V₁₊−Vₑᵣᵣ₁, and V2_{comp}=V₂₊−Vₑᵣᵣ₁ Eq. 5:

V3_{comp}=V3₊−Vₑᵣᵣ₂, and V4_{comp}=V4₊−Vₑᵣᵣ₂ Eq. 6:

V5_{comp}=V5₊−Vₑᵣᵣ₃, and V6_{comp}=V6₊−Vₑᵣᵣ₃ Eq. 7:

V7_{comp}=V7₊−Vₑᵣᵣ₄, and V8_{comp}=V8₊−Vₑᵣᵣ₄ Eq. 8:

Also, the following expression:

I×comp=V×comp/100;

where 100=100 Ω sense resistor for each channel in the illustrated embodiment, which of course can vary if needed depending on the valve of the sense resistor.
Given the above, a few notes:
1) R1, R2, R3, and R4 are “error” resistances, or “parasitic” resistances (in that they are being compensated for).
2) the compensation formula (and algorithm) requires all unknown input currents (I1 through I8) to first be measured, then their individual values are used within the algorithm, to allow compensation for all of the measured values.

As will be appreciated the algorithmic approach described above compensates for the “error resistances” (R1 through R4) which, at least in some uses of the instant application, can be the result of layout of a printed circuit board. These error resistances are additive to the precision sense 100 Ω resistors for each measurement channel. In some forms the algorithm requires that the (unknown) 4-20 mA currents are measured, and these measured valves are then used to calculate the amount of additive voltage error which is created for each channel. Once the error voltage for each channel is known, it can be subtracted from the measured values, thus completing the compensation (and yielding a more accurate result which has the error voltage removed from the measurement.

The formula set forth in FIG. 2 can be adjusted for any number of lanes and any number of channels in each of the lanes. At the most basic, the error correction set forth herein can be used with at least two separate channels occupying two separate lanes having a ground return location unique from the another lane. The approach can be expanded to accommodate any number of channels occupying any number of lanes. A pathway can be considered to be ground return at an appropriate location between an electrical component and ground (e.g. at a point after the 100 Ohm reference resistor).

Ground return can take on any useful form as will be appreciated. In one form the ground return may be a trace on a printed circuit board, such as would be the case when the channels are expressed in a PCB setting. In other embodiments, the ground return can be a single electrical wire/cable in which each of the separate lanes are connected at different locations.

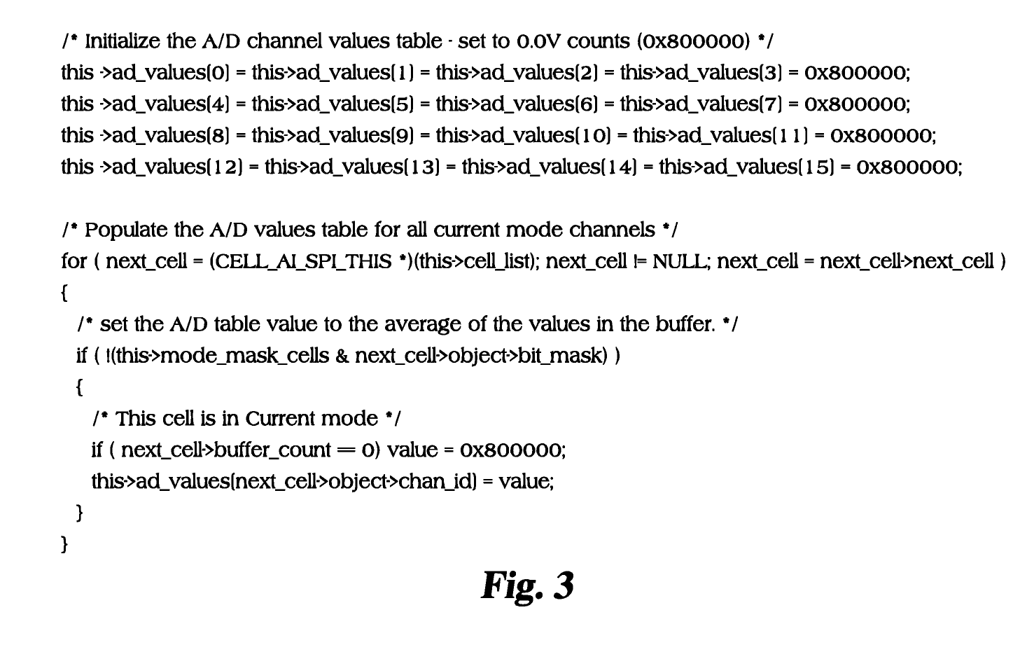

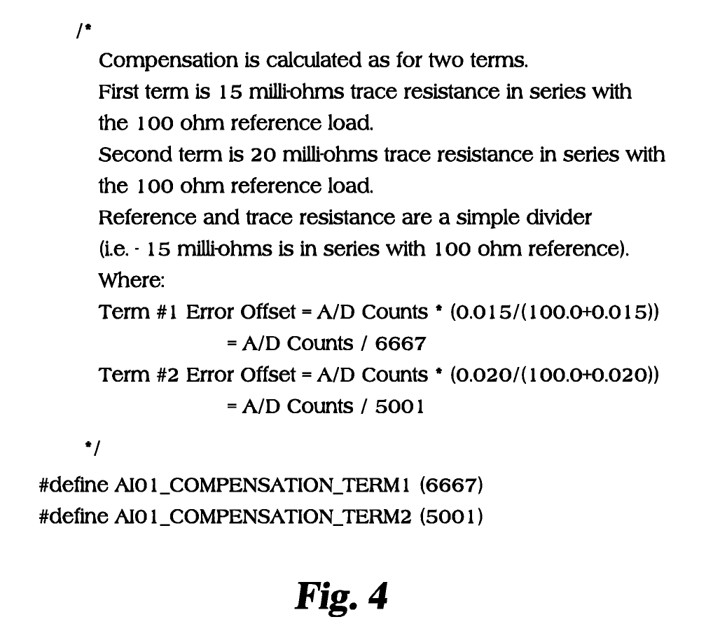

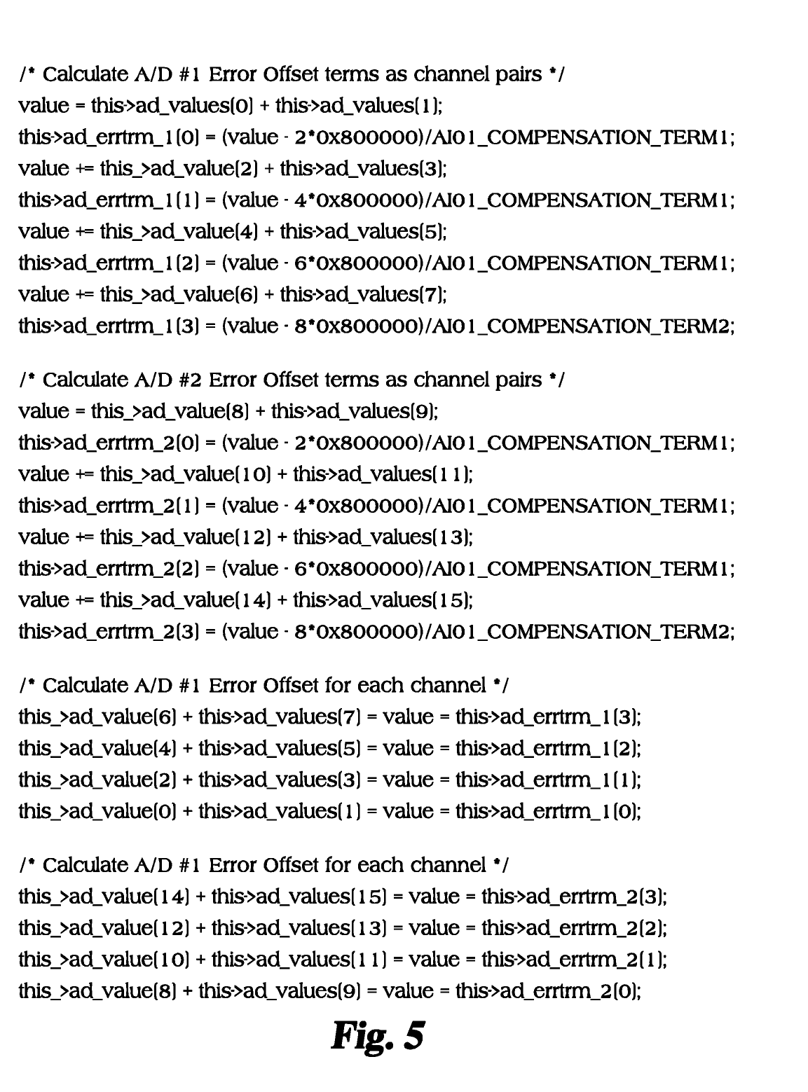

FIGS. 3-5 depict source code that implements the formula illustrated in FIG. 2, albeit with two separate analog to digital converters instead of just one depicted in FIG. 2. The source code is written in C and includes three parts (i.e. FIG. 3, FIG. 4, and FIG. 5) that when concatenated into a single file and compiled will produce voltage corrections in accordance with the formula provided in FIG. 2 (again, with the exception that the source code is accommodating two separate analog to digital converters, not one that is depicted in FIG. 2).

In one embodiment the measurements in each of the channels and lanes are used in an Analog to Digital Converter (ADC). The formula described herein can be incorporated into the ADC, it can be incorporated into a standalone processor, or can be located elsewhere in a Distributed Control System (DCS) environment. In one form the formula described herein can be incorporated into firmware, whether an initial firmware release or subsequent firmware updates.

In some forms the voltages of each channel that are used to determine current in the channels may be scanned at sufficient rate in a repeating sequential manner such that implementation of the formula is essentially performed in real-time. Other implementations may be considered.

The formula indicated in FIG. 2 and expressed in source code written in C in FIGS. 3-5 can alternatively be expressed as other types of circuits, whether analog or digital. Such digital circuits can be initially formulated in a high level computer instruction and ultimately expressed in, for example, a programmable logic controller, microprocessor, or the like. Thus, the formula can be expressed as a separate circuit to compute the offset corrections described in FIG. 2.

The embodiments depicted herein can be used to correct for errors in a printed circuit board application in a continuous (or near continuous) real-time manner, but can also be used to correct for those situations in which multiple field wires (i.e. ground wires) are consolidated into a single field wire where at least two separate channels are connected to the single wire at different locations. Such an implementation can consider the resistances in the ground return portion associated with each channel as merely a difference and not necessarily an error. Thus, though the discussion herein has highlighted correcting “errors” as such, it will be appreciated that any mention of “errors” can likewise apply to mere differences in resistance whether or not those differences are considered errors or mere artifacts of implementation.

One aspect the present application provides an apparatus comprising a correction circuit structured to receive information related to a first electrical flow property of a first channel and a second electrical flow property of a second channel, the circuit configured to determine a first error correction to the first electrical flow property and a second error correction to the second electrical flow property, the first error correction a function of both the first electrical flow property and the second electrical flow property, and the second error correction a function of both the first electrical flow property and the second electrical flow property.

A feature of the present application includes wherein the second error correction is also a function of a second resistance in a path that includes the second channel and the first error correction is also a function of the first resistance and the second resistance both of which are in a path that includes the first channel.

Another feature of the present application includes wherein the first electrical flow property is an electrical current of the first channel and the second electrical flow property is an electrical current of the second channel.

Still another feature of the present application includes wherein the correction circuit is implemented in a digital environment, the first electrical flow property is a measured electrical flow property, and the second electrical flow property is a measured electrical flow property.

Yet another feature of the present application includes wherein the correction circuit is an input/output device having analog input.

Still yet another feature of the present application includes wherein the correction circuit is implemented in an analog to digital converter.

Yet still another feature of the present application includes wherein the correction circuit is implemented in a microcontroller in electrical communication with an analog to digital converter, the analog to digital converter structured to receive the information related to electrical flow properties of the first channel and electrical flow properties of the second channel.

A further feature of the present application includes wherein the correction circuit is implemented in a distributed control system controller.

A still further feature of the present application includes wherein the correction circuit is implemented in a programmable logic controller.

A yet further feature of the present application includes wherein the correction circuit is a computer program instruction.

A still yet further feature of the present application includes wherein the first channel and the second channel are connected to a ground return path at different locations.

A yet still further feature of the present application further includes a first analog electrical path having the first channel and a second analog electrical path having the second channel, wherein the first channel is electrically coupled to the second channel via a ground return path, the first channel connected to the ground return path at a first connection location and the second channel connected to the ground return path at a second connection location different than the first connection location.

Another aspect of the present application provides an apparatus comprising a firmware update for correcting measurement voltages in light of error resistance in a first circuit pathway for a first sensor and an error resistance in a second circuit pathway for a second sensor, the firmware update including programming instructions to: receive a first current measurement from the first circuit pathway, receive a second current measurement from the second circuit pathway, calculate a first offset value for the first pathway as a function of the first current measurement and a first pathway resistance, and calculate a second offset value for the second pathway as a function of the a second pathway resistance, first current measurement, and the second current measurement.

Yet another aspect of the present application provides a method comprising: measuring a first resistance value in a first sensor circuit pathway, measuring a second resistance value in a second sensor circuit pathway, the second sensor circuit pathway having a different ground line pathway than the first sensor circuit pathway , and compiling a firmware load for installation in a computer memory, the firmware load characterized by a measurement offset correction that includes computation for a first offset correction as a function of a first current in the first sensor circuit pathway and the first resistance value, and computation for a second offset correction as a function of a second current in the second sensor circuit pathway, the second resistance, and the first resistance.

While the invention has been illustrated and described in detail in the drawings and foregoing description, the same is to be considered as illustrative and not restrictive in character, it being understood that only the preferred embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

1. An apparatus comprising:
a correction circuit structured to receive information related to a first electrical flow property of a first channel and a second electrical flow property of a second channel, the circuit configured to determine a first error correction to the first electrical flow property and a second error correction to the second electrical flow property, the first error correction a function of both the first electrical flow property and the second electrical flow property, and the second error correction a function of both the first electrical flow property and the second electrical flow property.

2. The apparatus of claim 1, wherein the second error correction is also a function of a second resistance in a path that includes the second channel and the first error correction is also a function of the first resistance and the second resistance both of which are in a path that includes the first channel.

3. The apparatus of claim 1, wherein the first electrical flow property is an electrical current of the first channel and the second electrical flow property is an electrical current of the second channel.

4. The apparatus of claim 1, wherein the correction circuit is implemented in a digital environment, the first electrical flow property is a measured electrical flow property, and the second electrical flow property is a measured electrical flow property.

5. The apparatus of claim 1, wherein the correction circuit is an input/output device having analog input.

6. The apparatus of claim 1, wherein the correction circuit is implemented in an analog to digital converter.

7. The apparatus of claim 1, wherein correction circuit is implemented in a microcontroller in electrical communication with an analog to digital converter, the analog to digital converter structured to receive the information related to electrical flow properties of the first channel and electrical flow properties of the second channel.

8. The apparatus of claim 1, wherein the correction circuit is implemented in a distributed control system controller.

9. The apparatus of claim 1, wherein the correction circuit is implemented in a programmable logic controller.

10. The apparatus of claim 1, wherein the correction circuit is a computer program instruction.

11. The apparatus of claim 1, wherein the first channel and the second channel are connected to a ground return path at different locations.

12. The apparatus of claim 1, which further includes a first analog electrical path having the first channel and a second analog electrical path having the second channel, wherein the first channel is electrically coupled to the second channel via a ground return path, the first channel connected to the ground return path at a first connection location and the second channel connected to the ground return path at a second connection location different than the first connection location.

13. An apparatus comprising:
a firmware update for correcting measurement voltages in light of error resistance in a first circuit pathway for a first sensor and an error resistance in a second circuit pathway for a second sensor, the firmware update including programming instructions to:
receive a first current measurement from the first circuit pathway;
receive a second current measurement from the second circuit pathway;
calculate a first offset value for the first pathway as a function of the first current measurement and a first pathway resistance; and
calculate a second offset value for the second pathway as a function of the a second pathway resistance, first current measurement, and the second current measurement.

14. A method comprising:
measuring a first resistance value in a first sensor circuit pathway;
measuring a second resistance value in a second sensor circuit pathway, the second sensor circuit pathway having a different ground line pathway than the first sensor circuit pathway; and
compiling a firmware load for installation in a computer memory, the firmware load characterized by a measurement offset correction that includes computation for a first offset correction as a function of a first current in the first sensor circuit pathway and the first resistance value, and computation for a second offset correction as a function of a second current in the second sensor circuit pathway, the second resistance, and the first resistance.

15. The apparatus of claim 2, wherein the first electrical flow property is an electrical current of the first channel and the second electrical flow property is an electrical current of the second channel.

16. The apparatus of claim 15, wherein the correction circuit is implemented in a digital environment, the first electrical flow property is a measured electrical flow property, and the second electrical flow property is a measured electrical flow property.

17. The apparatus of claim 2, wherein the correction circuit is an input/output device having analog input.

18. The apparatus of claim 2, which further includes a first analog electrical path having the first channel and a second analog electrical path having the second channel, wherein the first channel is electrically coupled to the second channel via a ground return path, the first channel connected to the ground return path at a first connection location and the second channel connected to the ground return path at a second connection location different than the first connection location.

19. The apparatus of claim 1, wherein the correction circuit is a computer program instruction; and
wherein the first channel and the second channel are connected to a ground return path at different locations.

20. The apparatus of claim 2, wherein the correction circuit is implemented in a digital environment, the first electrical flow property is a measured electrical flow property, and the second electrical flow property is a measured electrical flow property.
